(19) United States
(12) Patent Application Publication
(10) Pub. No.: US 2026/0169039 A1
(43) Pub. Date: Jun. 18, 2026

(54) POWER MONITORING DEVICE AND MAIN BOARD

(71) Applicant: ASUSTEK COMPUTER INC., Taipei (TW)

(72) Inventors: Kuo-Yi WANG, Taipei (TW); Cheng-Lun TSAI, Taipei (TW)

(21) Appl. No.: 19/246,142

(22) Filed: Jun. 23, 2025

(30) Foreign Application Priority Data
Dec. 17, 2024 (TW) 113149113

(51) Int. Cl. G01R 21/133; G01R 15/14; G01R 19/00; G01R 21/06; G06F 1/20

(52) U.S. Cl. CPC G01R 21/133; G01R 15/146; G01R 19/0038; G01R 21/06; G06F 1/20

(57) ABSTRACT

The disclosure provides a power monitoring device, which is applicable to a computer system. The computer system is arranged on a main board. The main board is connected to a power supply unit (PSU) through a power line to obtain power. The PSU includes a cooling fan. The power monitoring device includes a current monitoring module and a logic determining module. The current monitoring module is configured to detect an input current flowing through the power line to generate a current monitoring signal. The logic determining module is configured to obtain a system status signal of the computer system and the current monitoring signal, to generate an output value to be provided to the PSU for controlling the cooling fan. The disclosure further provides a main board.

### CROSS-REFERENCE TO RELATED APPLICATION

This application claims the priority benefit of Taiwan Application Serial No. 113149113, filed on Dec. 17, 2024. The entirety of the above-mentioned patent application is hereby incorporated by reference herein and made a part of specification.

### BACKGROUND OF THE INVENTION

### Field of the Invention

The disclosure relates to the technical field of main board power supplies, and in particular, to a power monitoring device and a main board.

### Description of the Related Art

Emergence of environment awareness and green energy deepens contradiction between scientific and technological progress and environment protection. Therefore, for a computer product (such as a main board), energy efficiency is a vital specification.

To improve energy efficiency, in a conventional technology, a power calculation function is added to a power supply unit (PSU) to adjust a system power consumption. However, this manner increases costs of the PSU, and cannot be applied to an existing PSU on the market having no power calculation function built therein.

### BRIEF SUMMARY OF THE INVENTION

The disclosure provides a power monitoring device, which is applicable to a computer system. The computer system is arranged on a main board. The main board is connected to a power supply unit (PSU) through a power line to obtain power. The PSU includes a cooling fan.

The power monitoring device includes a current monitoring module and a logic determining module. The current monitoring module is configured to detect an input current flowing through the power line to generate a current monitoring signal. The logic determining module is configured to obtain a system status signal of the computer system and the current monitoring signal, to generate an output value to be provided to the PSU for controlling the cooling fan.

The disclosure further provides a main board, which is applicable to a computer system, and is configured have a central processing unit installed thereon. The main board is connected to a PSU through a power line to obtain power. The PSU includes a cooling fan. The main board includes a power monitoring device and a control unit. The power monitoring device includes a current monitoring module and a logic determining module. The current monitoring module is configured to detect an input current flowing through the power line to generate a current monitoring signal. The logic determining module is configured to obtain a system status signal of the computer system and the current monitoring signal, to generate an output value to be provided to the PSU for controlling the cooling fan. The control unit is configured to obtain the current monitoring signal to control at least one operating parameter of the central processing unit.

Compared with the conventional technology, the power monitoring device provided in the disclosure detects the input current flowing through the power line to generate the current monitoring signal, and generates the output value based on the current monitoring signal and the system status signal to control the cooling fan. In this way, the cooling fan can operate based on an actual operating state of the computer system, to effectively adjust a system power consumption, thereby meeting a market energy saving specification (such as the Energy Star).

In addition, the power monitoring device of the disclosure may be arranged on the main board, and can control the operation of the cooling fan through the power line, and is applicable to various PSUs, including a PSU not equipped with a power calculation function. In addition, in the power monitoring device of the disclosure, the collected system status signal and current monitoring signal may be further provided to a back end of a computer for storage or calculation, to perform data analysis and utilization. The control unit on the main board may adjust the operating parameter of the central processing unit by using the data.

### BRIEF DESCRIPTION OF THE DRAWINGS

FIG. 1 is a schematic block diagram of a power monitoring device according to an embodiment of the disclosure;

FIG. 2 and FIG. 3 show an embodiment of an internal circuit of the power monitoring device in FIG. 1;

FIG. 4 is a partial schematic diagram of a power monitoring device according to another embodiment of the disclosure;

FIG. 5 shows a pin of a power line configured to connect a main board to a power supply unit (PSU) according to an embodiment of the disclosure; and

FIG. 6 is a schematic diagram of a main board assembly according to an embodiment of the disclosure.

### DETAILED DESCRIPTION OF THE EMBODIMENTS

Specific embodiments of the disclosure are described in more details below with reference to the schematic diagrams. Advantages and features of the disclosure become clearer based on the following descriptions and claims. It is to be noted that all of the figures are in a very simple form and in an inaccurate proportion, and are merely intended to conveniently and clearly describe the embodiments of the disclosure.

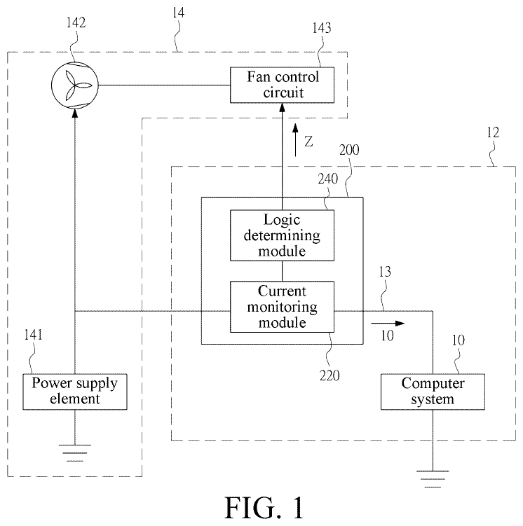

FIG. 1 is a schematic block diagram of a power monitoring device 200 according to an embodiment of the disclosure.

As shown in the figure, the power monitoring device 200 is applicable to a computer system 10. The computer system 10 includes a main board 12, and the main board 12 is connected to a power supply unit (PSU) 14 through a power line 13 to obtain power.

The PSU 14 includes a power supply element 141, a cooling fan 142, and a fan control circuit 143. The power supply element 141 is configured to provide power required for operation of the computer system 10 and the cooling fan 142. The fan control circuit 143 is configured to control operation of the cooling fan 142.

The power monitoring device 200 of the disclosure includes a current monitoring module 220 and a logic determining module 240.

The current monitoring module 220 is electrically coupled to the power line 13, and is configured to detect an input current I0 flowing through the power line 13 to generate a current monitoring signal Y.

The logic determining module 240 is electrically coupled to the current monitoring module 220, and is configured to obtain a system status signal W of the computer system 10 and the current monitoring signal Y from the current monitoring module 220, to generate an output value Z to be provided to the PSU 14.

In an embodiment, the fan control circuit 143 of the PSU 14 may obtain the output value Z through the power line 13, and control operation of the cooling fan 142 based on the output value Z.

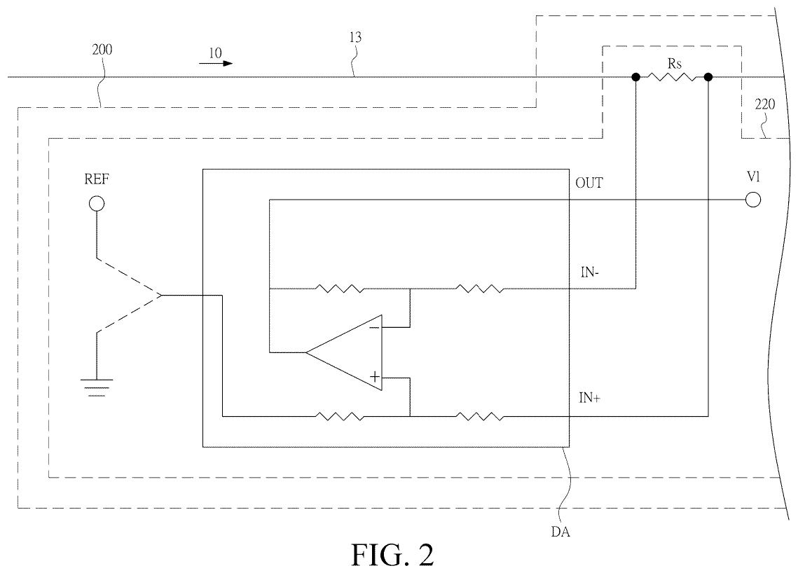

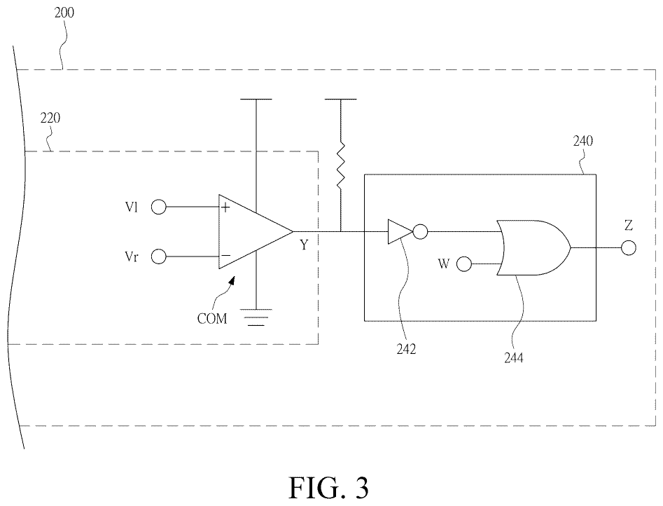

Referring additionally to FIG. 2 and FIG. 3, FIG. 2 and FIG. 3 show an embodiment of an internal circuit of the power monitoring device in FIG. 1.

As shown in the figure, the current monitoring module 220 includes a shunt resistor Rs, a differential amplifier DA, and a comparator COM.

The shunt resistor Rs is connected in series to the power line 13. The differential amplifier DA has two input terminals IN+ and IN− electrically coupled to the shunt resistor Rs, and is configured to obtain a potential difference between two terminals of the shunt resistor Rs and amplify the potential difference to generate a detection voltage V1, and transmit the potential difference to outside through an output terminal OUT.

The comparator COM is electrically coupled to the output terminal of the differential amplifier DA, and is configured to compare the detection voltage V1 with a reference voltage Vr to generate the current monitoring signal Y.

The logic determining module 240 includes a NOT gate 242 and an OR gate 244. The NOT gate 242 is configured to obtain the current monitoring signal Y to generate an inverted current monitoring signal YN. The OR gate 244 is configured to obtain the inverted current monitoring signal YN and the system status signal W to generate the output value Z.

In an embodiment, the system status signal W is set as follows. The system status signal W is logic 0 when the computer system 10 is in a powered-on state, and the system status signal W is logic 1 when the computer system 10 is in a powered-off state. The current monitoring signal Y is set as follows. The current monitoring signal Y is logic 1 when a power consumption of the computer system 10 is greater than or equal to a power consumption threshold, for example, 24 W, and the current monitoring signal Y is logic 0 when the power consumption of the computer system 10 is less than the power consumption threshold.

Specifically, if the computer system 10 is in the powered-on state and the power consumption of the computer system 10 is greater than or equal to the power consumption threshold, the output value Z is logic 0; if the computer system 10 is in the powered-on state but the power consumption of the computer system 10 is less than the power consumption threshold, the output value Z is logic 1; if the computer system 10 is in the powered-off state and the power consumption of the computer system 10 is greater than or equal to the power consumption threshold, the output value Z is logic 1; and if the computer system 10 is in the powered-off state and the power consumption of the computer system 10 is less than the power consumption threshold, the output value Z is logic 1.

In an embodiment, when the output value Z is logic 1, the fan control circuit 143 controls the cooling fan 142 in a different control mode. The fan control circuit 143 reduces a rotation speed of the cooling fan 142 or turns off the cooling fan 142. When the output value Z is logic 0, the fan control circuit 143 controls the cooling fan 142 in a different mode. The fan control circuit 143 increases the rotation speed of the cooling fan 142 or turns on the cooling fan 142.

In an embodiment, the fan control circuit 143 may include a control chip arranged in the PSU 14. The fan control circuit 143 may obtain the output value Z through the power line 13. However, the disclosure is not limited thereto. In other embodiments, the fan control circuit 143 may be arranged in the main board 12, and control the cooling fan 142 through the power line 13.

In the foregoing embodiment, the current monitoring module 220 includes a shunt resistor Rs, a differential amplifier DA, and a comparator COM, and is configured to detect the input current I0, so as to generate the current monitoring signal Y. However, the disclosure is not limited thereto. In an embodiment, the differential amplifier DA may be omitted, and the comparator COM is directly electrically coupled to the shunt resistor Rs. The comparator COM directly obtains a potential difference corresponding to the two terminals of the shunt resistor Rs, and compares the potential difference with the reference voltage Vr to generate the current monitoring signal Y. This embodiment is applicable to a situation in which the potential difference between the two terminals of the shunt resistor Rs can present a change of the input current I0 for generating the current monitoring signal Y.

In the embodiment of FIG. 2 and FIG. 3, the current monitoring signal Y outputted by the comparator COM is only used to generate the output value Z for controlling the operation of the cooling fan 142. However, the disclosure is not limited thereto.

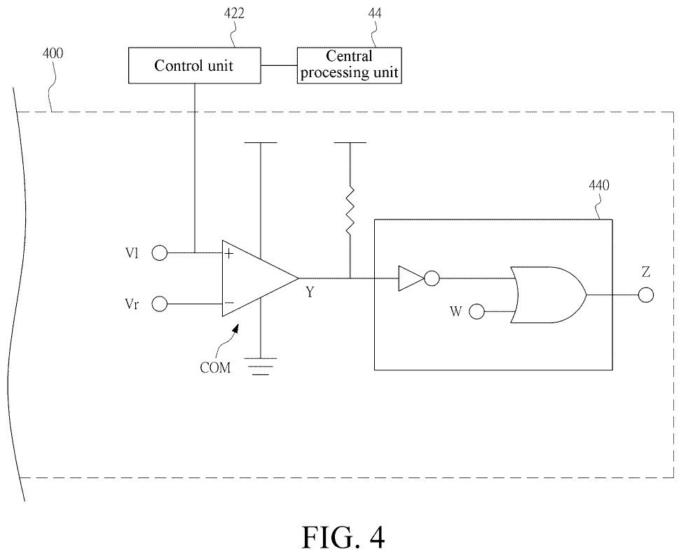

FIG. 4 is a partial schematic diagram of a power monitoring device 400 according to another embodiment of the disclosure.

The power monitoring device 400 is substantially similar to the power monitoring device 200 shown in FIG. 2 and FIG. 3, except that the current monitoring signal Y outputted by the comparator COM of the power monitoring device 400 of this embodiment, in addition to being provided to the logic determining module 440 to generate the output value Z for controlling the operation of the cooling fan 142, may be further provided to a computer system for subsequent processing. For example, as shown in the figure, the current monitoring signal Y may be provided to a control unit 422 on a main board (not shown). The control unit 422 may control at least one operating parameter of the central processing unit 44 based on the current monitoring signal Y. However, the disclosure is not limited thereto. In other embodiments, the computer system may store and analyze the current monitoring signal Y to determine a working mode of a user.

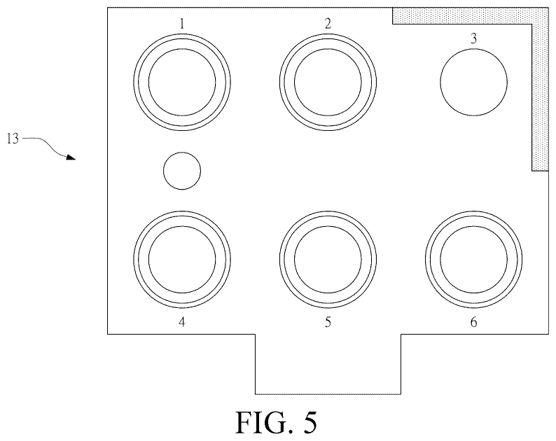

Referring additionally to FIG. 5, FIG. 5 shows a pin of the power line 13 configured to connect the main board 12 to the PSU 14 according to an embodiment of the disclosure. As shown in the figure, the power line 13 is a 6-pin power line 13. The output value Z generated by the logic determining module 240 may be transmitted to the fan control circuit 143 located in the PSU 14 through a pin 1.

However, the disclosure is not limited thereto. In other embodiments, the fan control circuit 143 may control the operation of the cooling fan 142 through a control line other than the power line 13.

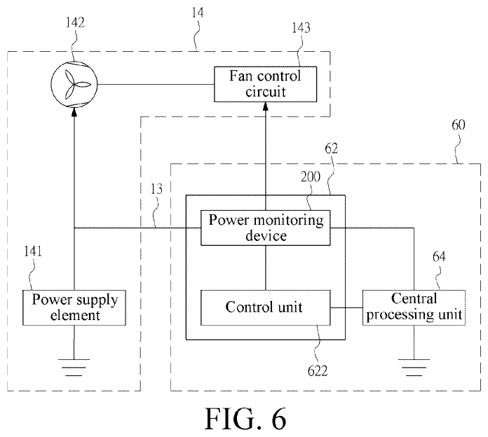

FIG. 6 is a schematic diagram of a main board assembly 60 according to an embodiment of the disclosure.

As shown in the figure, the main board component 60 includes a main board 62 and a central processing unit 64. The main board 62, in addition to including the power monitoring device 200, further includes a control unit 622.

The control unit 622 is electrically coupled to the central processing unit 64, and is configured to obtain the current monitoring signal Y to control at least one operating parameter of the central processing unit 64. For example, such operating parameters may be adjustable parameters that affect operating performance of the central processing unit 64, such as a frequency, a speed, and a working voltage of the central processing unit 64.

Specifically, referring additionally to FIG. 2, the current monitoring module 220 may monitor the input current I0 flowing through the power line 13 to generate the detection voltage V1 and the current monitoring signal Y. The control unit 622 may collect the data and store the data in a memory (not shown) for subsequent analysis and application. For example, the data may be used for analyzing a working mode of a user.

In addition, the control unit 622 may directly adjust the operating parameter of the central processing unit 64 based on the data. For example, if the control unit 622 detects that the current detection signal is logic 1, indicating that a power consumption of the computer system 10 is greater than or equal to a power consumption threshold, the control unit 622 may further determine whether the central processing unit 64 is in an overclocking state, and reduce an operating frequency of the central processing unit 64 if the central processing unit is in the overclocking state.

Based on the above, compared with the conventional technology, the power monitoring device 200 provided in the disclosure detects the input current I0 flowing through the power line 13 to generate the current monitoring signal Y, and generates the output value Z based on the current monitoring signal Y and the system status signal W to control the cooling fan 142. In this way, the cooling fan 142 can operate based on an actual operating state of the computer system, to effectively adjust a system power consumption, thereby meeting a market energy saving specification (such as the Energy Star).

In addition, the power monitoring device 200 of the disclosure may be arranged on the main board 12 or 62, and can control the operation of the cooling fan 142 through the power line 13, and is applicable to various PSUs 14, including a PSU 14 not equipped with a power calculation function. In addition, in the power monitoring device 200 of the disclosure, the collected system status signal W and current monitoring signal Y may be further provided to a back end of a computer for storage or operation, to perform data analysis and utilization. The control unit 622 on the main board 12 or 62 may adjust the operating parameter of the central processing unit 64 by using the data.

The above descriptions are merely preferred embodiments of the disclosure, and do not impose any limitation on the disclosure. Any form of change such as an equivalent replacement or modification made by any person skilled in the art to technical means and technical content provided in the disclosure without departing from scope of the technical means of the disclosure is content that does not deviate from the technical means of the disclosure, and still falls within the protection scope of the disclosure.

What is claimed is:

1. A power monitoring device, applicable to a computer system, the computer system being arranged on a main board, the main board being connected to a power supply unit (PSU) through a power line to obtain power, the PSU having a cooling fan, and the power monitoring device comprising:
a current monitoring module, configured to detect an input current flowing through the power line to generate a current monitoring signal; and
a logic determining module, configured to obtain a system status signal of the computer system and the current monitoring signal, to generate an output value to be provided to the PSU for controlling the cooling fan.

2. The power monitoring device according to claim 1, wherein the current monitoring module comprises:
a shunt resistor, connected in series to the power line;
a differential amplifier, configured to obtain a potential difference between two terminals of the shunt resistor and amplify the potential difference to generate a detection voltage; and
a comparator, configured to compare the detection voltage with a reference voltage to generate the current monitoring signal.

3. The power monitoring device according to claim 1, wherein the current monitoring module comprises:
a shunt resistor, connected in series to the power line; and
a comparator, configured to obtain a potential difference between two terminals of the shunt resistor and compare the potential difference with a reference voltage to generate the current monitoring signal.

4. The power monitoring device according to claim 1, wherein a central processing unit is arranged on the main board, the main board further comprises a control unit, and the control unit is configured to obtain the current monitoring signal to control at least one operating parameter of the central processing unit.

5. The power monitoring device according to claim 1, wherein a central processing unit is arranged on the main board, the main board further comprises a control unit, and the control unit is configured to obtain the current monitoring signal and the output value to control at least one operating parameter of the central processing unit.

6. The power monitoring device according to claim 1, wherein the logic determining module comprises a NOT gate and an OR gate, the NOT gate is configured to obtain the current monitoring signal to generate an inverted current monitoring signal, and the OR gate is configured to obtain the inverted current monitoring signal and the system status signal to generate the output value.

7. The power monitoring device according to claim 6, wherein the system status signal is logic 0 when the computer system is in a powered-on state, and the system status signal is logic 1 when the computer system is in a powered-off state.

8. The power monitoring device according to claim 6, wherein the current monitoring signal is logic 1 when a power consumption of the computer system is greater than or equal to a power consumption threshold, and the current monitoring signal is logic 0 when the power consumption of the computer system is less than the power consumption threshold.

9. The power monitoring device according to claim 6, wherein the PSU comprises a fan control circuit, the fan control circuit reduces a rotation speed of the cooling fan or turns off the cooling fan when the output value is logic 1, and the fan control circuit increases the rotation speed of the cooling fan or turns on the cooling fan when the output value is logic 0.

10. The power monitoring device according to claim 1, wherein the output value is transmitted to the PSU through the power line.

11. A main board, applicable to a computer system, and configured to have a central processing unit installed thereon, the main board being connected to a power supply unit (PSU) through a power line to obtain power, the PSU having a cooling fan, and the main board comprising:
a power monitoring device, comprising:
a current monitoring module, configured to detect an input current flowing through the power line to generate a current monitoring signal; and
a logic determining module, configured to obtain a system status signal of the computer system and the current monitoring signal, to generate an output value to be provided to the PSU for controlling the cooling fan; and
a control unit, configured to obtain the current monitoring signal to control at least one operating parameter of the central processing unit.
